(19) United States
(12) Patent Application Publication
(10) Pub. No.: US 2008/0091374 A1
(43) Pub. Date: Apr. 17, 2008

(54) Analog High Sensitivity Continuous Phase and Amplitude Detection Device for a Harmonic Microcantilever Sensor

(76) Inventor: Yuan-Jay Wang, Taipei (TW)

Correspondence Address: YUAN-JAY WANG, NO. 152, SEC. 3, BEISHAN RD., SHENKENG TOWNSHIP,, TAIPEI COUNTY 222, TAIPEI COUNTY, 222, TW

(21) Appl. No.: 11/944,622

(22) Filed: Nov. 25, 2007

(30) Foreign Application Priority Data
Feb. 24, 2006 (TW) 095106378

(51) Int. Cl. H03F 1/26

(52) U.S. Cl. 702/104

(57) ABSTRACT

An analog high sensitivity continuous phase and amplitude detection device for a harmonic microcantilever sensor which is widely used in ultra-high resolution measurement is developed in this patent. The aforementioned detection device contains a central control unit, a numerically-controlled oscillator, a dynamic driving signal magnitude compensator, a sensor-actuator, a microcantilever sensor, a current-to-voltage converter, a pre-amplifier, a low-pass filter, two analog phase-shifters, a root-mean-square converter, a sinusoidal-to-square wave converter, a phase angle difference converter, a band-pass filter, two dynamic signal magnitude compensators, and a multi-channel high resolution analog-to-digital converter. It detects continuously the very small phase variations between two sinusoidal signals in analog domain. The amplitude variation of the microcantilever sensor subject to the interactions of the external physical quantities is measured and converted into corresponding root-mean-square value. Accompanied with corresponding integrated circuits the phase and amplitude signal variations are transformed into related voltage signal variations. Both the phase and amplitude variations in terms of voltage are sampled using high resolution analog-to-digital converter to facilitate computer-based data analysis. The advantages of the proposed analog high sensitivity continuous phase and amplitude detection device are the low implementation cost, the continuous detection and transformation form, the ultra high phase and amplitude detection sensitivity, and the less coupling effects from amplitude variations of the considered signal to be measured.

### BRIEF DESCRIPTIONS OF THE DRAWINGS

FIG. 1 is a schematic view of an analog high sensitivity continuous phase and amplitude detection device for a harmonic microcantilever sensor of the invention.

FIG. 2 is a block diagram of a sinusoidal-to-square wave converter subsystem of the invention.
1: Central control unit.
2: Numerically-controlled oscillator.
3: Dynamic driving signal magnitude compensator.
4: Sensor-actuator.
5: Microcantilever sensor.
6. Four-quadrant laser beam detector.
7: Current-to-voltage converter.
8: Pre-amplifier.
9: Low-pass filter.
10: First phase-shifter.
11: Second phase-shifter.
12: Root-mean-square converter.
13: Sinusoidal-to-square wave converter.
14: Phase angle difference converter.
15: Low-pass filter.
16: Band-pass filter.
17: First dynamic signal magnitude compensator.
18: Second dynamic signal magnitude compensator.
19: Multi-channel high resolution analog-to-digital converter.
61: First amplifier.
62: First limiter.
63: Second amplifier.
64: Second limiter.
65: Third amplifier.
66: Third limiter.
67: Fourth amplifier.
68: Fourth limiter.

### BACKGROUND OF INVENTION

1. Field of the Invention

The invention relates to a new device for detecting continuously the variations of the phase and amplitude signals of a harmonic microcantilever sensor in the analog domain with high sensitivity. The aforementioned microcantilever sensor is driven by a piezo-plate device, which has piezoelectric regions controlled by piezo electrodes, sinusoidally at frequency near the resonance frequency. Once the external physical quantity acting on the microcantilever sensor varies, the amplitude and phase signals of the microcantilever sensor will change accordingly. These changes can be detected by the device of the invention.

2. Description of the Prior Art

A variety of techniques have been utilized to detect the variations of the phase and amplitude of a harmonic microcantilever sensor subject to the variations of physical properties acting on it. The present invention is widely used in scanning probe microscope to observe the topography of the surface of a semiconductor material. A scanning probe microscope is a microscope capable of observing a surface with an ultra-high resolution in nanometer or sub-nanometer range without damaging the surface.

U.S. Pat. No. 5,338,932 entitled “METHOD AND APPARATUS FOR MEASURING THE TOPOGRAPHY OF A SEMICONDUCTOR DEVICE” issued to Theodore et al. discloses an apparatus and method for performing a combination of atomic force microscopy and scanning tunneling microscopy measurements to provide an accurate representation of a surface's topography and a material composition. A variable flexibility probe of the apparatus includes a reference element, a variable stiffness element, a support member, a conductive tip and a force element. A first end of the reference element and a first end of the variable stiffness element are attached to the support member so that the reference and the variable stiffness element form two parallel cantilever arms that project from the support member. The force element is attached to both the reference and the variable stiffness element. The force element applies a variable force to the variable stiffness element in order to vary the stiffness or spring-constant of the variable stiffness element. Although the variable flexibility probe can perform a combination of atomic force microscopy and scanning tunneling microscopy measurements, it would be difficult to downscale the dimension of the variable flexibility probe in order to construct a system employing a plurality of the variable flexibility probes, since the variable flexibility probe is made of two parallel cantilever arms separated from each other with a small gap and including the force element there between.

U.S. Pat. No. 5,742,377 entitled “Cantilever for scanning probe microscope including piezoelectric element and method of using the same” issued to Minne et al. discloses a cantilever for a scanning probe microscope (SPM) including a piezoelectric element in a thicker, less flexible section near the fixed base of the cantilever and a piezoresistor in a thinner, more flexible section near the free end of the cantilever. When the SPM operates in the constant force mode, the piezoelectric element is used to control the tip-sample separation. Since the resonant frequency of the piezoelectric element is substantially higher than that of conventional piezoelectric tube scanners, much higher scan rates can be achieved. When the SPM operates in the dynamic or intermittent contact mode, a superimposed AD-DC signal is applied to the piezoelectric element, and the latter is used to vibrate the cantilever as well as to control the tip-sample spacing. In another embodiment the cantilever is supported on a knife edge and vibrates at a third or higher order resonant frequency.

U.S. Pat. No. 6,935,167 entitled “Harmonic cantilevers and imaging methods for atomic force microscopy” issued to Sahin et al. discloses a harmonic cantilever for use in a tapping-mode atomic force microscope including a cantilever arm and a probe tip. The cantilever arm has a shape selected to tune the fundamental resonance frequency or a resonance frequency of a selected higher order mode so that the fundamental and higher-order resonance frequencies have an integer ratio or near integer ratio. In one embodiment, the cantilever arm can be shaped to tune the fundamental resonance frequency. Alternately, the cantilever arm can include a geometric feature for tuning the resonance frequency of the fundamental mode or the selected higher order mode. An imaging method using the harmonic cantilever is disclosed whereby signals at the higher harmonics are measured to determine the material properties of a sample. In other embodiment, a cantilever includes a probe tip positioned at a location of minimum displacement of unwanted harmonics for suppressing signals associated with the unwanted harmonics.

### SUMMARY OF INVENTION

The main purpose of this invention is to provide a novel device capable of detecting continuously the variations of the amplitude and phase signals of a harmonic microcantilever sensor subject to the variations of external physical properties with high sensitivity in the analog domain. More precisely, the microcantilever sensor is driven harmonically near its resonance frequency while it is detecting the variations of the external physical properties. Once the external physical property acting on sensor varies, the amplitude and phase signal of the microcantilever sensor will vary accordingly. In the present invention, the amplitude and phase variations are transformed into related voltages by exploiting the proposed detection device. By observing the variations of these voltages, one can determine the variations of the physical quantities in the nearby of the microcantilever sensor. The main spirit of the proposed invention can be explained and understood by the following embodiments with corresponding figures.

### DETAILED DESCRIPTION OF THE PREFERRED EMBODIMENTS

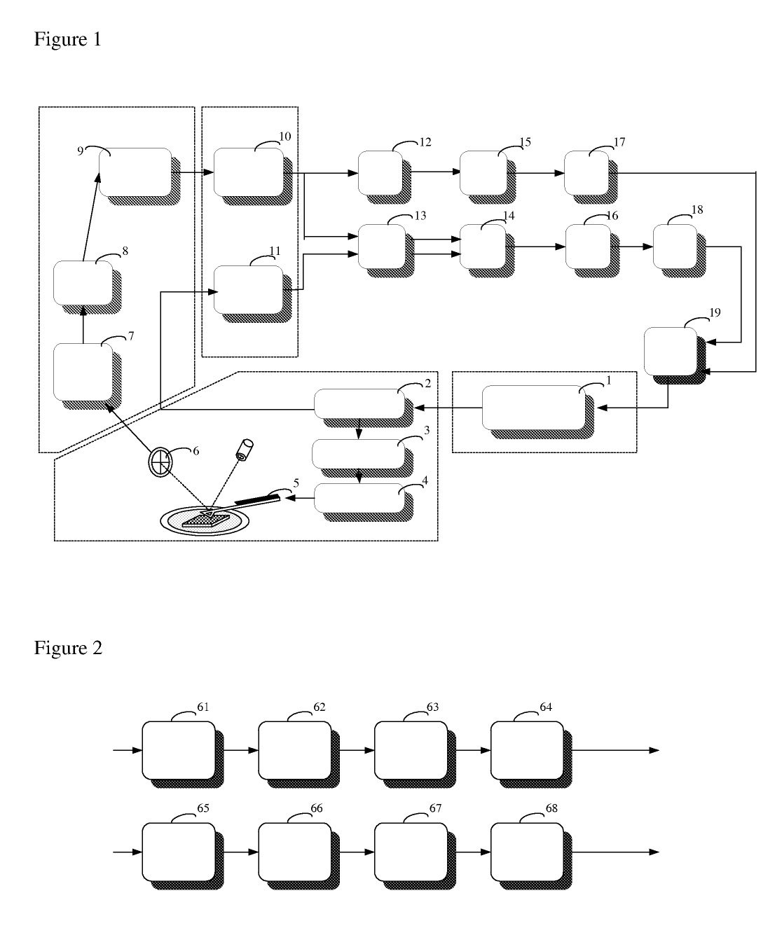

The present invention and its purposes are described in detail in the followings by referring to the attached embodiment figures:
1. First, as shown in FIG. 1, a central control unit (1) is exploited to decide the working frequency in one respect. The working frequency, once it is decided, will be converted into corresponding digitalized signals to control the numerically-controlled oscillator (2) to generate a sinusoidal working signal with specified frequency to drive the microcantilever sensor (5). In another respect, the phase and amplitude-related signals are converted into their related digitalized signals by using the multi-channel high resolution analog-to-digital converter (19). These digitalized signals are fed into the aforementioned central control unit (1) to perform data analysis and inspection.
2. With reference to FIG. 1, a numerically-controlled oscillator (2), receiving digital control signals from the central control unit (1), is utilized to generate sinusoidal working signal with specified frequency. The said sinusoidal working signal is both utilized as a signal to feed into the dynamic driving signal magnitude compensator (3) and as a reference sinusoidal signal to feed into the second phase-shifter (11) to perform phase angle difference measurement. As compared with other proposed inventions, the said method to generate a sinusoidal working signal for operation is simpler. The implementation cost is low, since it needs only one numerically-controlled oscillator (2) and could provide simultaneously the sinusoidal working and reference signals.
3. FIG. 1 shows a dynamic driving signal magnitude compensator (3), which is proposed here to dynamically control the amplitude of the said sinusoidal working signal generated by the numerically-controlled oscillator (2) to accommodate sensor actuator (4) with different driving sensitivity. In other words, the said dynamic driving signal magnitude compensator (3) is developed to dynamically control the amplitude of the driving signal of the sensor-actuator (4) to achieve specified oscillation amplitude of the microcantilever sensor (5).
4. Shown as FIG. 1, a sensor-actuator (4) fabricated using the piezoelectric bimorph cell, which receives the said sinusoidal working signal from the dynamic driving signal magnitude compensator (3) and is used to drive the microcantilever sensor (5) to perform a sinusoidal motion with pre-specified frequency and amplitude.
5. As shown in FIG. 1, the amplitude and phase signals of the microcantilever sensor (5), driven sinusoidally with specified amplitude and frequency, will vary with respect to the variations of the external physical quantities, such as temperature, pressure, humidity, and atomic force interactions acting on the microcantilever sensor (5). The application field of the present detection device is broader than the other proposed inventions. In addition to topography observation of materials in nanometer degree, it can be used to do physical quantities measurement with variations in nano-scale.
6. It is shown in FIG. 1 that a four-quadrant laser beam detector (6) is exploited to simultaneously detect the lateral and longitudinal amplitude variations of the microcantilever sensor (5) subject to external physical quantities variations. More precisely, the amplitude variations of the microcantilever sensor (5) subject to force variations both in the lateral and longitudinal directions acting on it will yield in current variations in every quadrant of the four-quadrant laser beam detector (6).
7. Referring to FIG. 1, a current-to-voltage converter (7) is used to convert the above-mentioned current variations in every quadrant of the four-quadrant laser beam detector (6) into corresponding signal in terms of voltage. The said current variations will change with respect to the variations of the physical properties acting on the microcantilever sensor (5).
8. As shown in FIG. 6, a pre-amplifier (8) is innovated to suitably amplify the magnitude of the output signal of the current-to-voltage converter (7) to facilitate following signal analysis and processing.
9. With reference to FIG. 1, a low-pass filter (9) is used to filter out the high frequency noise induced by the microcantilever sensor (5) while doing measurement and by the measuring environment. The output signal of the low-pass filter (9) is called a measured sinusoidal signal in the following.
10. FIG. 1 shows that a first phase-shifter (10) which is used to suitably schedule the phase angle of the measured sinusoidal signal in the output of the low-pass filter (9) to maintain a static phase angle difference of 0, 90, 180, and 270 degrees between the measured sinusoidal signal and the reference sinusoidal signal. The conversion sensitivity between the phase angle difference and its related voltage is the best while the static phase angle difference is at an angle of 0, 90, 180, and 270 degrees.
11. Meanwhile, FIG. 1 shows that a second phase-shifter (11) which receives sinusoidal reference signal from the numerically-controlled oscillator (2) and is used to suitably schedule the phase angle of the signal in the output of the numerically-controlled oscillator (2) to maintain a static phase angle difference at an angle of 0, 90, 180, and 270 degrees between the sinusoidal measured and reference sinusoidal signals.
12. Shown as FIG. 1, a root-mean-square converter (12) which has a converter input and a converter output and is employed to convert the amplitude of the said measured sinusoidal signal into a direct current signal at the converter output, wherein the value of the direct current signal at the converter output is indicative of the RMS value of the applied signal, and wherein the signal at the converter output comprises a non-time varying direct current component. Once the microcantilever sensor (5) encounters external physical properties variations acting on it, the oscillation amplitude of it in the sinusoidal form will change accordingly. This change will also yield in the variations of the voltage in the output of the root-mean-square converter (12). In other words, the non-time varying direct current component in the output of the root-mean-square converter (12) will change with respect to the variations of the amplitude of the microcantilever sensor (5).
13. As shown in FIG. 2, a sinusoidal-to-square wave converter (13), which has a converter input and a converter output and contains a two-stage amplifier and limiter circuit topology and is used to convert the said sinusoidal measured and reference signals into corresponding square wave signals with limited amplitude. The two mentioned square wave signals are named reference square wave and measured square wave signals, respectively. The sinusoidal-to-square wave converter (13) could be easily implemented using operation amplifiers and diodes with low cost.
14. Accordingly, the two square wave signals in the output of the said sinusoidal-to-square wave converter (13) are transmitted into the phase angle difference converter (14). The phase angle difference converter (14), having two inputs and one output, allows us to convert the phase angle difference between the two square wave signals into related voltage signals. More precisely, the said measured square wave signal with a specified frequency is applied to one of the input terminals of the said phase angle difference converter (14). The said reference square wave signal of the same frequency is applied to the reference input terminal of the said phase angle difference converter (14). The output signal of the said phase angle difference converter (14) will be proportional to both the magnitude and the phase angle difference of the mentioned measured and reference square waves. Since the magnitude of the square wave signals of the said phase angle difference converter (14) are clamped, the output of it can be used as a direct indication of the phase angle difference between the described measured sinusoidal signal and the reference sinusoidal signal. Hence, once the microcantilever sensor (5) encounters external physical properties variations acting on it, the phase angle of the measured sinusoidal signal of it in the sinusoidal form will change accordingly. Then, the phase angle difference of the two square wave signals will change in accordance with the change of the external physical properties acting on the microcantilever sensor (5).
15. As shown in FIG. 1, a low-pass filter (15), having one input and one output, is designed to filter out the high frequency component of the output signal of the root-mean-square converter (12).
16. It is shown in FIG. 1 that a band-pass filter (16), having one input and one output, is designed to filter out both the direct-current component in the output of the phase angle difference converter (14) and the high frequency noise induced while measuring. The said direct-current component in the output of the phase angle difference converter (14) is generated from the magnitude of the aforementioned square wave signals. Using the band-pass filter (16) to acquire exactly the phase angle difference-related signal in terms of voltage has never been indicated in the proposed inventions.
17. As shown in FIG. 1, a first dynamic signal magnitude compensator (17), having one input and one output, is developed to dynamically compensate the amplitude of the voltage signal in the output of the root-mean-square converter (12), which is related to the oscillation amplitude of the microcantilever sensor (5).
18. Also, as shown in FIG. 1, a second dynamic signal magnitude compensator (18), having one input and one output, is developed to dynamically compensate the amplitude of the voltage signal in the output of the band-pass filter (16), which is related to the phase angle difference of the microcantilever sensor (5).
19. With reference to FIG. 1, a multi-channel high resolution analog-to-digital converter (19), having sixteen inputs and one output, is presented to simultaneously convert the aforementioned amplitude-related and phase-related signals of the microcantilever sensor (5) into corresponding digitalized signal to facilitate computer-aided data analysis, signal observation and monitoring.

What is claimed is:

1. An analog high sensitivity continuous phase and amplitude detection device for a harmonic microcantilever sensor, which is used as a sensing mechanism to continuously detect the variations of the external physical quantities acting on a microcantilever sensor operating at its resonance frequency, comprising:
(a) a central control unit, which is used to decide both the working frequency of the microcantilever sensor and the corresponding digital signals to generate a sinusoidal working signal with the aforementioned working frequency; and
(b) a sensor excitation and detection subsystem, which receives the digital signals from the said central control unit, and is used to generate a sinusoidal working signal with specified amplitude and frequency for the microcantilever sensor and to detect the variations of the amplitude of the microcantilever sensor; said sinusoidal working signal with specified amplitude and frequency is also used as a reference sinusoidal signal to do phase angle difference measurement; and
(c) a signal conversion, amplification, and noise filtering subsystem, which receives output signal from the said sensor excitation and detection subsystem, and is used to suitably convert and amplify the sensor-detected signal and to filter out the noise of the sensor-detected signal; said sensor-detected signal is called the measured sinusoidal signal; and
(d) a phase-shifter subsystem, which receives output signal from the said signal conversion, amplification, and noise filtering subsystem and is used to suitably shift the phase angle of the said measured sinusoidal signal and the reference sinusoidal signal; and
(e) a amplitude and phase signals conversion subsystem, which receives output signal from the said phase-shifter subsystem and is used to simultaneously real-time detect the variations of the amplitude and phase signals of the microcantilever sensor subject to variations of external physical quantities; and
(f) a dynamic signal magnitude compensator subsystem, which receives output signal from the said amplitude and phase signals conversion subsystem and is used to compensate the magnitude of the amplitude and phase signal-related voltage signals of the microcantilever sensor; and
(g) a multi-channel high resolution analog-to-digital converter subsystem, which receives output signal from the said dynamic signal magnitude compensator subsystem and is used to convert the aforementioned amplitude and phase signal-related voltage signals into corresponding digital signals; the said digital signals are then inputted into the said central control unit for analysis.

2. An analog high sensitivity continuous phase and amplitude detection device for a harmonic microcantilever sensor of claim 1 wherein the said sensor excitation and detection subsystem comprises
(a) a numerically-controlled oscillator, which is used to generate a sinusoidal working signal with specified frequency; and
(b) a dynamic driving signal magnitude compensator, which is cascaded with the said numerically-controlled oscillator and is used to dynamically control the amplitude of the aforementioned sinusoidal working signal with specified frequency; and
(c) a sensor-actuator, which is cascaded with the said dynamic driving signal magnitude compensator and is used to drive a piezo-ceramic device to generate a sinusoidal oscillation with specified frequency and amplitude to actualize the microcantilever sensor; and
(d) a microcantilever sensor, which is mounted on the said sensor-actuator and is used to detect the variations of external physical quantities acting on the sensor.

3. An analog high sensitivity continuous phase and amplitude detection device for a harmonic microcantilever sensor of claim 1 wherein the said signal conversion, amplification, and noise filtering subsystem includes a current-to-voltage converter, a pre-amplifier, and a low-pass filter; said current-to-voltage converter converts the sensor-detected current signal into corresponding voltage signal; said pre-amplifier is cascaded with the current-to-voltage converter to suitably amplify the sensor-detected signal; said low-pass filter is cascaded with the pre-amplifier and is used to filter out the high frequency noise in the output of the said pre-amplifier.

4. An analog high sensitivity continuous phase and amplitude detection device for a harmonic microcantilever sensor of claim 1 wherein the said phase-shifter subsystem contains a first phase-shifter and a second phase-shifter; said first phase-shifter is used to suitably shift the phase angle of the said measured sinusoidal signal; said second phase-shifter is used to suitably shift the phase angle of the said reference sinusoidal signal.

5. An analog high sensitivity continuous phase and amplitude detection device for a harmonic microcantilever sensor of claim 1 wherein the said amplitude and phase signals conversion subsystem comprises:
a root-mean-square converter, which receives output signal from the said first phase-shifter and is used to convert the amplitude-related measured sinusoidal signal into its corresponding voltage signal; and
a sinusoidal-to-square wave converter, which is used to convert the said measured sinusoidal signal and the said reference sinusoidal signal, respectively, in the output of the first phase-shifter and the second phase-shifter, into related square wave signals, said related square wave signals are the measured square wave signal and the reference square wave signal; and
a phase angle difference converter, which receives output signal from the said sinusoidal-to-square wave converter and is used to detect the phase angle difference between the measured square wave signal and the reference square wave signal; the aforementioned phase angle difference is converted into a phase-related voltage signal; and
a low-pass filter, which is cascaded with the said root-mean-square converter and is used to filter out the high frequency noise in the output of the said root-mean-square converter; and
a band-pass filter, which is cascaded with the said phase angle difference converter and is used to filter out both the low and high frequency noises in the output of the said phase angle difference converter.

6. An analog high sensitivity continuous phase and amplitude detection device for a harmonic microcantilever sensor of claim 5 wherein the said sinusoidal-to-square wave converter comprises a first amplifier, a first limiter, a second amplifier, a second limiter, a third amplifier, a third limiter, a fourth amplifier, and a fourth limiter; the said first amplifier, first limiter, second amplifier, and second limiter are used to convert the measured sinusoidal signal in the output of the first phase-shifter into related measured square wave signal with the same frequency; the said third amplifier, third limiter, fourth amplifier, and fourth limiter are used to convert the reference sinusoidal signal in the output of the second phase-shifter into related reference square wave signal with the same frequency.

7. An analog high sensitivity continuous phase and amplitude detection device for a harmonic microcantilever sensor of claim 1 wherein the said dynamic signal magnitude compensator subsystem contains a first dynamic signal magnitude compensator and a second dynamic signal magnitude compensator; said first dynamic signal magnitude compensator is used to dynamically compensate the amplitude-related voltage signal of the sensor in the output of the said low-pass filter to facilitate signal observation; said second dynamic signal magnitude compensator is used to dynamically compensate the phase-related voltage signal of the sensor in the output of the said band-pass filter to facilitate signal observation.
